(19) United States
(12) Patent Application Publication
(10) Pub. No.: US 2022/0177094 A1
(43) Pub. Date: Jun. 9, 2022

(54) SURFACE PROTECTION AGAINST CAVITATION EROSION

(71) Applicants: Otto-Von-Guericke-Universitat Magdeburg, Magdeburg (DE); King Abdullah University of Science and Technology, Makkah (SA)

(72) Inventors: Claus-Dieter Ohl, Magdeburg (DE); Silvestre Roberto Gonzalez-Avila, Magdeburg (DE); Dang Minh Nguyen, Magdeburg (DE); Himanshu Mishra, Makkah (SA)

(73) Assignees: Otto-Von-Guericke-Universitat Magdeburg, Magdeburg (DE); King Abdullah University of Science and Technology, Makkah (SA)

(21) Appl. No.: 17/435,895

(22) PCT Filed: Mar. 6, 2020
(86) PCT No.: PCT/EP2020/056032

§ 371 Date: Sep. 2, 2021

(30) Foreign Application Priority Data
Mar. 6, 2019 (EP) 19000116.4

(51) Int. Cl. B63H 1/18; C23C 16/02; C23C 16/04; C23C 16/455

(52) U.S. Cl. CPC B63H 1/18; C23C 16/45525; C23C 16/045; C23C 16/0245

(57) ABSTRACT

The present invention relates to a method for protecting surfaces of components against cavitation erosion and components provided with such cavitation protection surfaces, wherein in the surface a plurality of microcavities is provided which entrap gas such as air; the gas, air, entrapped inside the microcavities expands in the vicinity of cavitation bubbles, forming a gas cushion layer that directs cavitation jets away from the surface, thereby protecting the surface against cavitation erosion; the cavitation having a reentrant or double reentrant inlet design with typical T-shape and T-shape profile

The present invention relates to a method for protecting surfaces of components against cavitation erosion and components provided with such cavitation protection surfaces.

In particular the present invention relates to a pathway for the design of cavitation repellent surfaces.

Cavitation erosion is a well-known problem, caused by the collapse of vapor bubbles near solid boundaries in high-speed flows, such as around ship rudders, pumps, and flow bends, and leading to repair and downtime of the equipment.

These bubbles appear when the pressure in the liquid falls below the saturation pressure. As these bubbles collapse in the vicinity of a solid surface, microjets and shock waves of large amplitude are generated which can impact on the wall at up to ˜80 m/s. Repeated or cyclic collapse of cavitation bubbles on the surface leads to surface fatigue failure and subsequent erosion of the surface. Thus, it is a serious cause of concern for cavitation damage beside the undesirable noise and mechanical vibration commonly associated to cavitating flows.

Due to the high costs associated with the repair and downtime of the equipment, the prevention and mitigation of cavitation-related damage remains an area of intense research and development. A variety of strategies have been explored for mitigating cavitation, including surface-hardening and liquid-repellent coatings. However, those approaches are not only limiting due to their costs and environmental impact, but they also ultimately give in to the violent activity of cavitation bubbles and high-speed jets.

It is experimentally and theoretically established that cavitation bubbles collapsing near a solid boundary are accelerated towards it with the high-speed jet impacting onto the solid boundary, but bubbles collapsing near a free boundary, such as a liquid-vapor interface, are repelled and so is the jet.

Further, it is known that water-repellant coatings can trap air/vapor at the solid-liquid interface, thus simulating a free surface. However, most common coatings, typically comprising perfluorinated chemicals, are vulnerable to abrasion and high mechanical and thermal stresses during engineering flows besides posing health and environmental concern due on release of detrimental chemicals to the environment.

It was the object of the present invention to provide a method for protecting surfaces subject to cavitation against cavitation erosion and to provide components equipped with such cavitation protection surface.

In particular, it was the object to provide a cavitation protection which does not need specially hardened materials nor chemical coatings which are liable to wear not only causing decreasing protection but also environmental pollution.

The problem of cavitation erosion relates to all materials used in the production of components, such as inorganic, non-metallic, metallic and organic materials, materials such as plastics, fiber reinforced composites, glasses besides metals and their alloys.

For overcoming this problem according to the method of the present invention a plurality of microcavities is provided in the surface to be protected against cavitation erosion, wherein the cavities have an inlet at the surface with horizontal overhang and an at least 90° turn at the lower edge of the horizontal overhang towards the inner wall of the cavity referred to the longitudinal axis of the cavity, such design being also referred to as reentrant cavities (RCs).

According to a further embodiment a vertical overhang is provided at the fee end of the horizontal overhang wherein the turn at the lower edge of the vertical overhang towards the inner wall is at least 90° referred to the longitudinal axis of the cavity, such design being also referred to as double reentrant cavities (DRCs). Both, the reentrant cavities as well as the double reentrant cavities can efficiently entrap gas/air. Thus, they are also referred to as “gas entrapping microcavities” (1).

Surfaces provided with such gas-entrapping microcavities, in the following also referred to “gas entrapping microtextured surfaces” (GEMs), can present a ‘free’ surface to cavitation bubbles, leading to a coating-free strategy for mitigating cavitation.

By the microcavities of the present invention wettability of surfaces is significantly reduced compared to surfaces without such structures for both polar as well as non-polar liquids. GEMs of the present invention have an apparent contact angle of greater than 90°, such surfaces qualify as omniphobic surfaces. In particular, contact angles as high as 130° to 150° are observed. With the microcavities of the present invention with reentrant and double reentrant features intrinsically wetting materials can be rendered repellent to liquids (omniphobic).

The present invention relates to a biomimetic approach to entrap air at the solid-liquid interface. The inspiration for this approach came from nature. Sea-skaters (Halobates germanus) and springtails (Collembola) have evolved amazing strategies to repel liquids to thrive in open oceans, and soils, respectively. Specifically, their cuticle consist of mushroom-shaped features, microtrichia (2) and granules (3) respectively, that enable the robust entrapment of air on accidental submersion in water for breathing and buoyancy.

According to the present invention the microcavities can have an overall cylindrical shape with an inlet at one end and a bottom at the opposite end.

The reentrant microcavities have an overall T-shaped profile with horizontal overhang at the top and the double reentrant cavities, also referred to as mushroom shaped cavities, a vertical overhang at the free end of the horizontal overhang like a serife T.

“Micorocavities” means that they can have a diameter D in the order of magnitude of about 20 μm to about 250 μm, and a depth of about 30 μm to 120 μm, preferably 30 μm to 80 μm, and most preferably 40 μm to 80 μm. Preferably the pitch L, the distance between two adjacent microcavities measured from center to center, is about D+5 to D+50 μm, more preferably about D+5 to D+30 μm and in particular D+5 to D+20 μm.

The pitch L should be sufficiently large in order to ensure sufficient mechanical stability. If the pitch is too small mechanical stability might be affected.

The magnitude of the width and the height of horizontal overhang is about several micrometer, typically less than 10 micrometer (depending on the diameter of the cavity); and the width of the vertical overhang is less than the width of the horizontal overhang and the height a few micrometers, for example about 2 μm to about 6 μm, preferably about 2.5 μm to 4.5 μm.

It is to be noted that the above mentioned dimensions are not mandatory but serves for illustration of the magnitude of the microcavities only. According to need the dimensions can be varied.

For forming the gas entrapping microtextured surface of the present invention the plurality of microcavities is, preferably, regularly distributed over the surface to be protected.

According to a preferred embodiment the microcavities are arranged with a hexagonal symmetry over the surface. However the present invention is not restricted to such hexagonal distribution but other pattern of arrangement can be also suitably used, for example in parallel consecutively arranged rows, in staggered rows etc.

The arrangement and number of microcavities should be such that in case of cavitation the air entrapped in the cavities can provide a free surface like environment for providing effective cavitation protection.

The key idea of the present invention is to robustly entrap air in the microcavities and inducing the entrapped air to protrude onto the surface by the pressure field generated by the cavitation bubbles on expansion. The protruding air acts like an air-cushion layer or impact shield.

According to the present invention the GEMs can repel the microjets or at least significantly reduce the amplitude depending on the distance of the cavitation bubbles from the surface with which they impinge on the surface.

In any case, the surface is protected from the bombardment of the liquid jet impact. Further, there is the great advantage that the performance of the GEMs does not require additional chemical coatings.

Nevertheless, it is also possible to use the GEMs in combination with water repellant coatings as referred to later on with reference to a coating of perfluorodecyltrichlorosilane (FDTS). It has been experimentally established by the present inventors that for GEMs with and without such coatings the cavitation jet behavior is very similar.

There are several techniques for re-supplying the gas to the cavities to continue protecting the surface in case the GEMs have been deactivated by a cavitation event occurring very close to the boundary.(5, 6)

For example, gas can be supplied from the back of the substrate. Here, the cavitation bubble may provide the pull on the gas reservoir for the refill. Further, the gas dissolved in the liquid can be used. Having suitable nano/microstructured substrates the surfaces may heal through diffusion (7, 8).

As explained in detail in the Experimental Section, the GEMs of the present invention can be produced by photolithographic processes.

Further suitable methods are 3-D printing, additive manufacturing and laser micromachining.

In the following the present invention is illustrated in more detail by reference to the figures showing a preferred embodiment of the present GEMs with RCs and DRCs, respectively,

It is shown in:

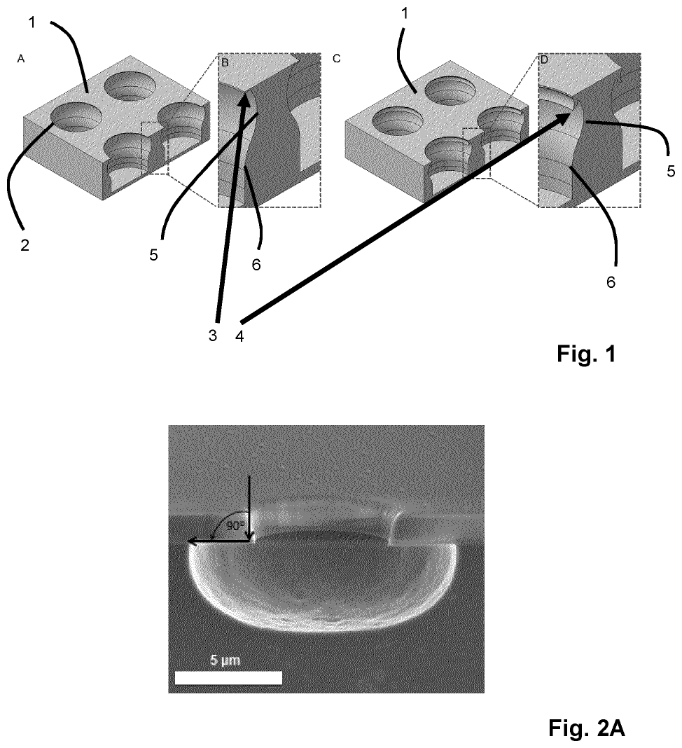

FIG. 1A, B, C, D schematical lateral plan view of reentrant cavity with horizontal overhang (A, B), and of double reentrant cavity with horizontal and vertical overhang (C, D),

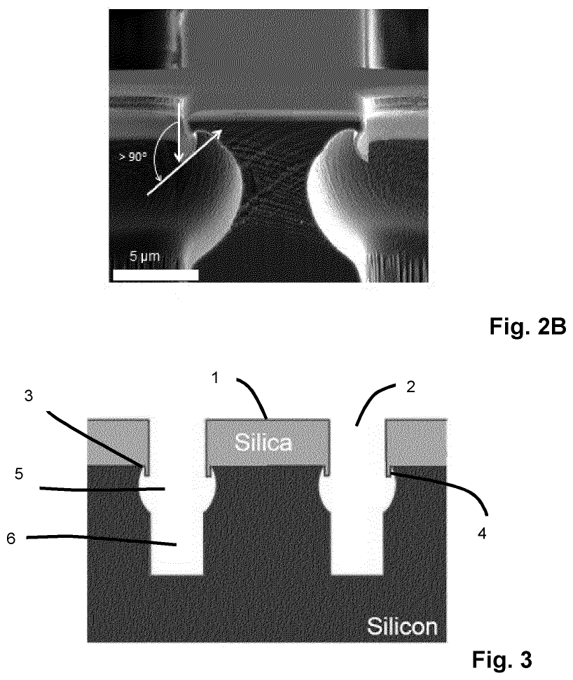

FIG. 2A, B scanning electron micrographs of reentrant (A) and double re-entrant microcavity indicating the at least 90° turns,

FIG. 3 a longitudinal cross-section through two adjacent double reentrant cavities representing a GEMs,

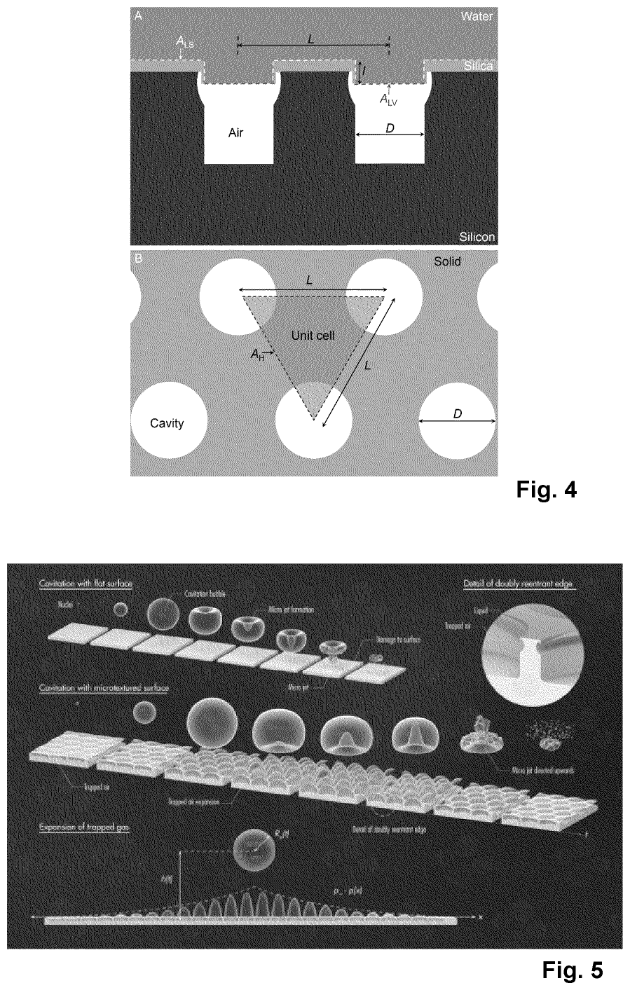

FIG. 4 A the cross-section of FIG. 3 with the GEMs immersed in water,

FIG. 4 B a top view onto the GEMs of FIGS. 3 and 4 with hexagonal arrangement of the microcavities,

FIG. 5 an illustration that summaries on how the GEMs prevent damage from cavitation jet,

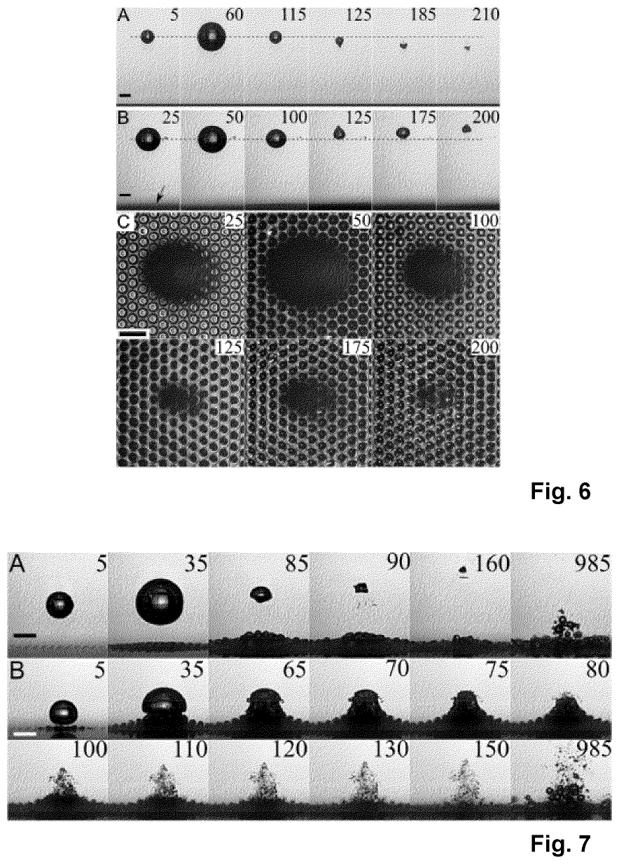

FIG. 6 A, B, C the bubble dynamics close to a solid flat boundary compared with similar cavitation event close to the gas-entrapping microtextured surface,

FIG. 7 the bubble dynamics on nucleation at a distance closer to the GEMs than in FIG. 6, and

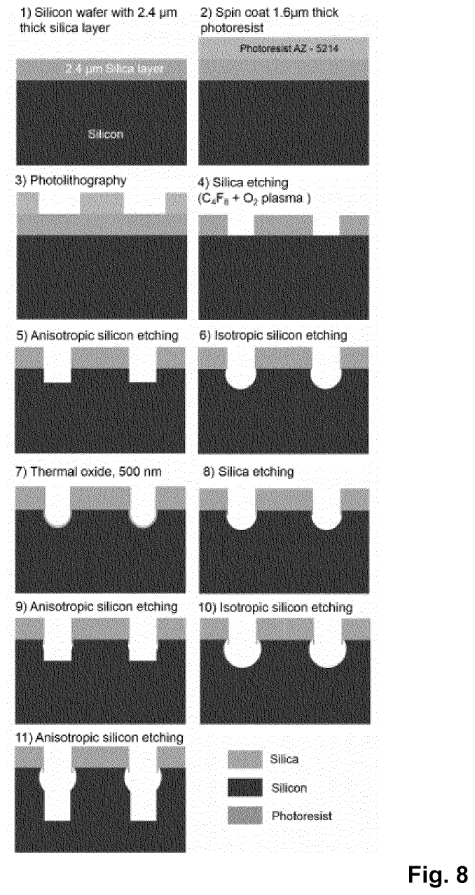

FIG. 8 a schematic illustration of a microfabrication process for the production of the present microcavities with double re-entrant inlet.

If not indicated otherwise in the figures for the GEMs a model system was used with an array of circular microcavities in a plane silicon substrate having a thin thermal oxide layer, wherein the microcavities are arranged in hexagonal distribution.

Cavitation bubbles were produced by laser induction for focusing thermal energy at a controlled distance from the surface, and inception of nucleation, expansion and collapse of cavitation bubbles were observed by high speed imaging.

For providing an objective benchmark for the distance between cavitation bubble and surface a non-dimensional parameter γ=δ/Rmax is introduced with δ being the distance between inception of nucleation and surface, and Rmax being the maximal radius of the bubble. With δ>Rmax means there is no contact of the bubble with the surface, δ≤Rmax the bubble comes into contact with the surface.

The typical design of a reentrant cavity and double reentrant cavity, respectively, is shown in FIG. 1A with enlarged section 1B as well as FIG. 1C with enlarged section in FIG. 1D. From the enlarged sections B and D the typical T-shape profile of the reentrant cavity with horizontal overhang 3 and mushroom-shaped profile with additional vertical overhang 4 of the double reentrant cavity is clearly visible. Further, there is a concave curvature 5 in the wall with a diameter which is larger than the diameter of the inlet 2 at the surface 1, and a shaft-like deepening 6 downwards, referred to “shaft”.

In the scanning electron micrographs of FIG. 2A the 90° turn of a RC and in FIG. 2B the double reentrant structure with a turn of more than 90° are indicated by the arrows. The reentrant microcavity in FIG. 2A has a profile like a half-shell, but typically the depth is increased as shown in FIG. 1.

A longitudinal cross-section of a typical design of the present DCRs with its characteristic overhanging profile is shown in FIG. 3. The microcavities are here provided in a plane substrate made of silicon with thin thermal oxide layer.

Referring to FIG. 3 the structure of the microcavities can be roughly divided into three parts, namely the inlet 2, a curvature part 5 and a shaft 6.

The DRCs have a cylindrical base structure with diameter D and inlet 2, a region with ring-shaped concave curvature 5 with maximal diameter Dc greater than D, and a vertical overhang 3 extending downwards from the junction of inlet 2 to curvature 5.

Typically the length of the vertical overhang is less than 0.5 of the height of the curvature, preferably less than 0.3 of the height of the curvature.

The situation with the GEMs of FIG. 3 immersed into liquid is shown in FIG. 4 A.

The interface between solid surface and liquid (A_{LS}) and liquid and vapor (air, A_{LV}), respectively, is indicated by the dashed line.

The liquid extends into the microcavity until the free edge of the vertical overhang 4 and air is entrapped in the microcavity.

In FIG. 2 “L” is the pitch between two adjacent microcavities (the distance measured from center to center), and “I” the length of the liquid column extending into the microcavity (distance between A_{LS} and A_{LV}).

A preferred hexagonal arrangement of the microcavities for the GEMs is shown in FIG. 4B with triangular unit cell, indicated by dashed triangle, with equilateral pitch L, diameter D of microcavities and area of the unit cell A_{H},

FIG. 5 shows an illustration of the present strategy to repel cavitation bubbles by means of the GEMs with DRCs by reference to selected sets of high speed images.

For comparison in the upper set of images nucleation and progress of cavitation on a flat glass surface without GEMs is shown. The middle set shows the fate of cavitation bubbles with GEMs according to invention and the lower set illustrates the course of expansion of gas trapped in the microcavities.

On cavitation event on flat surfaces upon nucleation the bubbles expand to their maximum radial size and, then, collapse. During collapse they move towards the surface forming liquid jets which are directed towards the surface. These jets impinge onto the surface with high impact velocity and cause damage of the surface.

It is shown (from the left) in the upper row “cavitation with flat surface”: nuclei-cavitation bubble-micro jet formation-micro jet-damage to surface; in the middle row “cavitation with microtextured surface”: trapped air-trapped air expansion-detail of doubly re-entrant edge-micro jet directed upwards; in the lower row “expansion of trapped gas”: course of expansion of the gas and trapped inside the GEMs induce by the pressure field of the cavitation bubble.

To the contrary, on cavitation with GEMs the liquid jet from the bubble collapsing close to the GEMs is directed away from the substrate. Further, by the bubbles a pressure field is generated which induces expansion of the gas entrapped in the microcavities. As shown in the lower set of images, as the bubble approaches the entrapped gas protrudes and behaves as if a liquid-gas interface, i.e. a free surface.

The highlighted circle in the upper left corner of FIG. 5 is an enlarged view of the circular section outlined in the third image from the left of the middle set and shows the GEMs with air protruding from the microcavities of the GEMs covered by liquid.

FIGS. 6 and 7 show sequences of scanning electron images of bubble dynamics depending on the distance of the bubbles from the GEMs with DRCs and for comparison of cavitation bubbles generated next to a flat glass substrate.

The dotted line at the location of nucleation of the bubbles is for a better visualisation of the bubbles' motion. The bottom black line indicates the location of the boundary, the length of the scale bars is 500 μm and numbers on the images refer to time in microseconds after inception of nucleation.

In FIG. 6 A selected images of the bubble dynamics near a flat glass surface is depicted for γ=4.8 and maximum radius of the bubble Rmax=630 μm. The bubble expand to the maximum radial size at t=60 μs and collapses around t=120 μs. During collapsing the bubble moves noticeably towards the substrate at the bottom and forms liquid jets, that can damage the surface.

To the contrary bubbles created near the present GEMs have a favourably altered dynamics at similar conditions:

Cavitation bubbles with γ=5.1 and Rmax=610 μm expand and collapse as in FIG. 6 A, but the liquid jets point away from the substrate provided with GEMs as evidenced by the upward motion of the centroid (FIG. 6 B). Simultaneously, the gas entrapped in the microcavities expands as indicated with an arrow in the first image of FIG. 6 B and as shown in FIG. 6 C with a top view of the cavitation progress of FIG. 6 B.

The entrapped gas bulges out of the microcavities during early state of expansion, t=25 μs, reach a nearly hemispherical shape at t=50 μs, and shrink in size during collapse of the bubbles.

A stable rejection of bubbles away from the boundary is observed in repeated experiments with almost identical dynamics.

The situation of nucleation closer to the substrate provided with present GEMs is shown in FIG. 7 for γ=1.8 and Rmax=530 μm (FIG. 5 A), γ=0.7 and Rmax=430 μm (FIG. 5 B), the length of the bars being 500 μm.

Referring to FIG. 7 A, on nucleation closer to the boundary the pressure exerted on the GEMs and entrapped gas, respectively, is lowered, resulting in a larger volume of entrapped gas protruding from the microcavities. The bubbles' collapse is between t=85 μs and t=95 μs with a shape which is very similar to the shape of bubbles collapsing near a free boundary with the centroid of the bubbles moving away from the boundary.

The entrapped gas forms gas bubbles, which still adhere to the surface but protrude outside the microcavities. As a result, the microcavities are filled partially with liquid and are deactivated.

It is assumed that this deactivation may have multiple causes such as coalescence of the bubbles during the large expansion, growth of the bubbles through gas diffusion and depinning of the contact lines from the double re-entrant microcavities.

At distances even closer to the boundary, a regime was reached where the cavitation bubble coalesced with the gas bubbles on the surface. An example of this event is shown in FIG. 7B (γ=0.7 and Rmax=430 μm). The cavitation bubble connects with the gas bubbles during expansion. With this gain of gas, the collapse take place much later, at t=130 μs (a bubble of similar size next to a solid boundary collapsed in ≈80 μs (17)). This is consistent with a cushioned impact velocity of the main bubble onto the boundary of ≈10 m/s, which is significantly lower than the value of ≈80 m/s found for a rigid boundary.

In cases with deactivation of the microcavities means can be provided for re-activating the microcavities by refill with gas as referred to in the section preceding the description of the figures.

### Experiments

Following the recently reported design principles for creating robust GEMs (2), arrays of circular cavities with mushroom-shaped inlets were microfabricated in a hexagonal lattice on SiO₂/Si surfaces. This spatial arrangement maximizes the liquid-vapor surface area—the free boundary—perceived by the cavitation bubbles. Cavities with diameters, D=50 μm and 200 μm, with pitch L=D+12 μm and also the performances of GEMs were compared with those coated with perfluorodecyltrichlorosilane (FDTS).

1. Experimental Setup

The test section, filled with deionized water, was an acrylic cuvette where the GEMs was attached to one of the walls, as portrayed in FIGS. 3 and 5 B. The bubble was generated by triggering a single pulse from a laser (wavelength 532 nm, Q-switched Nd:YAG laser with pulse duration 6 ns and pulse energy of approximately 1 mJ) focused at specific locations from the GEMs. Two high-speed cameras were used to record the cavitation events. The side view was captured with a Photron (Photron Fastcam SA1.1), as shown in FIG. 5 B, equipped with a 60 mm macro lens (Nikor) at full magnification (resolution 20 μm per pixel). The scene was back-illuminated with mildly diffused light from a Revox LED fiber optic lamp (SLG 150V). The top-view camera (Photron Fastcam SAX2) was coupled to an MP-E 65 mm Canon lens set at 2× magnification to obtain a resolution of 10 μm per pixel, as depicted in FIG. 6C. The lens observed the front-illuminated scene from the same illumination source from a double light guide (Sumita AAAR-007W 1.5 in length). Framing rates were 200,000 frames/s except for FIG. 4b which was captured at 40 kfps. A pulse delay generator (Berkley Scientific, BNC model 575) triggered and synchronized the laser and the two high-speed cameras.

Confocal Microscopy was performed in a Zeiss LSM710 microscope to visualize the entrapment of air inside cavities of GEMs on submersion in water containing Rhodamine B.

2. Fabrication of Doubly Reentrant Cavities

Referring to FIG. 8 with a schematic illustration the microfabrication process of the doubly reentrant microcavities is explained in detail.

Gas entrapping microtextured surfaces (GEMs) were designed using Tanner EDA L-Edit software and the patterns were transferred to photoresist-covered silicon wafers using a Heidelberg Instrument μPG501 direct-writing system.

1) Silicon wafers were used (4-inch diameter, <100> orientation with a 2.4 μm thick thermal oxide layer from Silicon Valley Microelectronics).

2) The wafers were spin-coated with a 1.6 μm layer of AZ-5214 photoresist.

3) The patterns were designed using Tanner EDA L-Edit software and transferred to wafer in a Heidelberg Instruments μPG501 direct-writing system. The UV-exposed photoresist was removed in a bath of AZ-726 developer.

4) The exposed SiO₂ top layer was etched away in an inductively coupled plasma (ICP) reactive-ion etching (RIE) instrument by Oxford Instruments (pressure, 10 mT; radio frequency (RF) power, 100 W; ICP power, 1500 W; C₄F₈ at 40 sccm and O₂ at 5 sccm, at T=10° C. for 13 min).

5) The wafer was transferred to a Deep ICP-RIE to etch the Si under the SiO₂ layer using an anisotropic etching method (Bosch process) which was characterized by a sidewall profile control using alternating deposition of a C₄F₈ passivation layer (pressure, 30 mT; RF power, 5 W; ICP power, 1300 W; C₄F₈ at 100 sccm and SF6 at 5 sccm, at T=15° C. for 5 s) and etching with SF₆ (pressure, 30 mT; RF power, 30 W; ICP power, 1300 W; C₄F₈ at 5 sccm and SF₆ at 100 sccm, at T=15° C. for 7 s). This process was conducted 4 times, which corresponded to an etching depth of ≈2 μm. 6) After a piranha cleanse (H₂SO₄/H₂O₂=4:1) at T=115° C. for 10 min, an isotropic etching step was performed (pressure, 35 mT; RF power, 20 W; ICP power, 1800 W; SF₆ at 110 sccm, at T=15° C. for 25 s). 7) Then, a 500 nm layer of thermal oxide was grown over the etched wafer, using a Tystar furnace system. 8) The top and bottom layers of the thermal oxide were subsequently etched similarly to the first SiO₂ etching step described in step 4. 9) The Bosch process (described in step 5) was repeated 5 times to prepare the cavities for step 10) an isotropic etching step (as described in step 6) for 135 s, to create a void behind the added thermal oxide sidewall, which then formed the doubly reentrant rim at the edge of the microcavity. 11) The final step deepened the cavities up to ≈60 μm, using the same Bosch process, now for 155 cycles. The samples were cleaned in fresh piranha solution, rinsed in DI water, blown dry with a N₂ pressure gun, and thoroughly dried in a dedicated vacuum oven at 50° C. until the θ₀ of smooth silica stabilizes at ≈40° (ca. 48 h). The sample were then stored in a N₂ cabinet until needed for characterization.

RCs can be produced by an analogous process, however without the steps of forming vertical overhang.

3. Molecular Vapor Deposition of Perfluorodecyltrichlorosilane (FDTS) on Silica Surfaces

Some of the silica GEMs obtained according to 2. Fabrication process set out above were covalently grafted with perfluorodecyltrichlorosilane (FDTS).

Perfluorodecyltrichlorosilane (FDTS) was chemically grafted onto the microtextured silica surfaces via a microprocessor-controlled ASMT Molecular Vapor Deposition (MVD) 100E system. Prior to the FDTS deposition, the cleaned silica surfaces were exposed to a 100 W oxygen plasma for 2 min to activate the surface, i.e., to generate surface hydroxyl groups. Subsequently, the silica surfaces were placed in the MVD to expose the gas-phase FDTS molecules. The reaction chamber was purged with nitrogen gas to get rid of the by-products from previous processes and unreacted FDTS. Next, the vaporized FDTS and deionized water were introduced into the chamber, which was maintained at 308 K. The reaction time was set for 15 min.

4. Assessment of Wettability

Wettability tests were conducted with SiO₂/Si wavers, used as model system, with arrays of microcavities with double reentrant inlets and for comparison without the microtexture of the present invention using water.

TABLE 1

| | | | Doubly reentrant edge |
|---|---|---|---|
| Surfaces | Diameter D, μm | Pitch L, μm | length I, μm |
| C1 | 200 | 212 | 3.1 |
| C2 | 50 | 62 | 3.1 |

Additional experiments were carried out with said surfaces with FDTS deposition. The advancing/receding contact angles were measured by dispensing/retracting the liquids at a rate 0.2 μL/s and the apparent contact angles for water on the GEMs was found to be θ>120° (omniphobic) as shown in table 2 below.

TABLE 2

| | Contact angles of water droplet | | |
|---|---|---|---|
| Surfaces | | Coating free | FDTS deposition |
| Flat silica | θᵣ | 40° ± 2° | 113° ± 1° |
| C1 | θᵣ | 128° ± 2.4° | 141° ± 1° |
| C2 | θᵣ | 105° ± 2° | 130° ± 1° |

5. Assessment of Capability to Entrap Air on Immersion

A Zeiss LSM710 upright confocal microscope was used to visualize the air entrapment/liquid-air interface. Microtextured silica surface with doubly reentrant cavities was immersed in water and rhodamine B solution and a 20× water immersion objective lens was used to observe the water meniscus under z≈5 mm thick column of water. Robust entrappment of air was confirmed.

### LIST OF REFERENCES AS CITED

1. E. M. Domingues, S. Arunachalam, H. Mishra, Doubly Reentrant Cavities Prevent Catastrophic Wetting Transitions on Intrinsically Wetting Surfaces. Acs Appl Mater Inter 9, 21532-21538 (2017).
2. L. Cheng, Marine and freshwater skaters: differences in surface fine structures. Nature 242, 132 (1973).
3. J. Nickerl, R. Helbig, H.-J. Schulz, C. Werner, C. Neinhuis, Diversity and potential correlations to the function of Collembola cuticle structures. Zoomorphology 132, 183-195 (2013).
4. G. A. Mahadik et al., Superhydrophobicity and Size Reduction Allowed Water Striders to Colonize the Ocean. (Under review), (2019).
5. Y. H. Xue, P. Y. Lv, H. Lin, H. L. Duan, Underwater Superhydrophobicity: Stability, Design and Regulation, and Applications. Applied Mechanics Reviews 68, (2016).
6. C. Lee, C.-H. Choi, C.-J. Kim, Superhydrophobic drag reduction in laminar flows: a critical review. Experiments in Fluids 57, (2016).
7. M. Amabili, A. Giacomello, S. Meloni, C. M. Casciola, Unraveling the Salvinia paradox: design principles for submerged superhydrophobicity. arXiv preprint arXiv:1612.01769, (2016).
8. E. Lisi, M. Amabili, S. Meloni, A. Giacomello, C. M. Casciola, Self-recovery superhydrophobic surfaces: Modular design. ACS nano 12, 359-367 (2017).
9. A. Vogel, W. Lauterborn, Acoustic transient generation by laser-produced cavitation bubbles near solid boundaries. The Journal of the Acoustical Society of America 84, 719-731 (1988).

### LIST OF REFERENCE NUMBERS

1 surface
2 inlet
3 horizontal overhang
4 vertical overhang
5 curvature
6 shaft

1. A method for protecting a surface of a component against cavitation erosion,
wherein in the surface a plurality of microcavities is provided
wherein the microcavities have an inlet (2) at the surface (1) with horizontal overhang (3), or
wherein the microcavities have an inlet (2) at the surface (1) with horizontal overhang (3) and a vertical overhang (4) provided at the free end of the horizontal overhang (3),
both with a turn of at least 90° with reference to the longitudinal axis of the cavity.

2. The method according to claim 1,
wherein the microcavities have a circular shape with a diameter of several micrometres to several hundred of micrometres and a depth of several micrometres to several tens of micrometres.

3. The method according to claim 1,
wherein the diameter of the cavity increases below the inlet (2).

4. The method according to claim 3,
wherein by the increased diameter a region with concave curvature (5) is provided extending along the circumference of the inner wall of the cavity.

5. The method according to claim 1,
wherein the cavity has a basic cylindrical shape.

6. The method according to claim 1,
wherein the microcavities are arranged in a hexagonal geometry onto the surface (1) of the component.

7. A component with cavitation protected surface,
wherein at least part of the surface (1) exposed to cavitation is provided with a plurality of microcavities according to claim 1 for entrapping gas as protection against cavitation erosion.

8. The component according to claim 7,
wherein at least the surface (1) of the component is made of an inorganic, non-metallic, a metallic, an organic material, or a composite material thereof.

9. Use of a cavitation protected surface according to claim 1 in the production of neutron spallation sources, ship rudders, pumps, flow bends, turbines, marine propellers, in thermoelectric power generation, in boosting waters through long distances, and marine transportation.

10. The method according to claim 2,
wherein the diameter of the cavity increases below the inlet (2)

11. The method according to claim 2,
wherein by the increased diameter a region with concave curvature (5) is provided extending along the circumference of the inner wall of the cavity.

12. The method according claim 2,
wherein the cavity has a basic cylindrical shape.

13. The method according claim 3,
wherein the cavity has a basic cylindrical shape.

14. The method according claim 4,
wherein the cavity has a basic cylindrical shape.

15. The method according to claim 1,
wherein the microcavities are arranged in a hexagonal geometry onto the surface (1) of the component.

16. The method according to claim 2,
wherein the microcavities are arranged in a hexagonal geometry onto the surface (1) of the component.

17. The method according to claim 3,
wherein the microcavities are arranged in a hexagonal geometry onto the surface (1) of the component.

18. The method according to claim 4,
wherein the microcavities are arranged in a hexagonal geometry onto the surface (1) of the component.

19. The method according to claim 5,
wherein the microcavities are arranged in a hexagonal geometry onto the surface (1) of the component.
